(19) United States
(12) Patent Application Publication
(10) Pub. No.: US 2016/0026224 A1
(43) Pub. Date: Jan. 28, 2016

(54) INFORMATION PROCESSING SYSTEM AND METHOD OF CONTROLLING INFORMATION PROCESSING SYSTEM

(71) Applicant: FUJITSU LIMITED, Kawasaki-shi (JP)

(72) Inventor: Yasutomo SAKURAI, Kawasaki (JP)

(21) Appl. No.: 14/723,683

(22) Filed: May 28, 2015

(30) Foreign Application Priority Data
Jul. 25, 2014 (JP) 2014-151786

(51) Int. Cl. G06F 1/20; H05K 7/20

(52) U.S. Cl. CPC G06F 1/206; H05K 7/20218

(57) ABSTRACT

A disclosed information processing system includes a plurality of information processing devices cooled by cooling water; a plurality of chillers each configured to circulate the cooling water to and from the plurality of the information processing devices; a flow monitor unit configured to monitor a total flow volume, where the total flow volume being a sum of a flow volume of each cooling water of the plurality of the chillers; and adjustment units each provided to each of the chiller, where the adjustment unit being configured to adjust an individual flow volume of the cooling water in the corresponding chiller, such that the total flow volume monitored by the flow monitor unit becomes equal to a set value suitable for cooling the plurality of the information processing devices.

### CROSS-REFERENCE TO RELATED APPLICATION(s)

This application is based upon and claims the benefit of priority of the prior Japanese Patent Application No. 2014-151786, filed on Jul. 25, 2014, the entire contents of which are incorporated herein by reference.

### FIELD

The embodiments discussed herein are related to an information processing system and a method of controlling an information processing system.

### BACKGROUND

With the advent of an advanced information society, the volume of data handled in information processing devices such as servers is increasing. Accordingly, an amount of heat generation by such information processing devices is also increasing. The information processing device needs to be cooled so as to prevent it from deterioration in performance due to the increase in amount of heat generation.

Methods of cooling the information processing device are classified into an air-cooling method and a water-cooling method. In the water-cooling method, an information processing device is cooled by circulating primary cooling water between a chiller and the information processing device, and causing a heat exchanger to perform heat exchange between the primary cooling water and secondary cooling water which circulates in the information processing device.

Besides the function to cool the primary cooling water warmed by the information processing device, the chiller also has a function to circulate the primary cooling water to and from the information processing device.

When the chiller is stopped by a breakdown, the circulation of the primary cooling water is stopped, and hence the information processing device is not cooled. As a result, the cooling of the secondary cooling water is also stopped, and there arises a risk that the information processing device is broken down. To deal with this problem, in the water-cooling method, two chillers are provided in order to increase redundancy, and one of the chillers is provided as an operation system while the other is provided as a standby system. According to this method, the operation system usually performs the cooling, while the standby system performs the cooling only when the operation system breaks down.

In this case, in order not to change the cooling ability when switching from the operation system to the standby system, it is preferable to use the chillers of the same specifications and the same performance for each of the operation system and the standby system.

However, when the two chillers are restricted to the same performance in this manner, the range for choice of the chillers is narrowed. Moreover, since the same two chillers are provided, it is wasteful in terms of cost.

The techniques related to the present application are disclosed in Japanese Laid-open Patent Publications Nos. 07-235789, 2005-315255, 61-125634, 02-257207, and 02-75873.

### SUMMARY

According to one aspect discussed herein, there is provided an information processing system including: an information processing system including: a plurality of information processing devices cooled by cooling water; a plurality of chillers each configured to circulate the cooling water to and from the plurality of the information processing devices; a flow monitor unit configured to monitor a total flow volume, where the total flow volume being a sum of a flow volume of each cooling water of the plurality of the chillers; and adjustment units each provided to each of the chiller, where the adjustment unit being configured to adjust an individual flow volume of the cooling water in the corresponding chiller, such that the total flow volume monitored by the flow monitor unit becomes equal to a set value suitable for cooling the plurality of the information processing devices.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a schematic diagram of an information processing system according to a first embodiment;

FIG. 2 is a flowchart for explaining a method of controlling the information processing system according to the first embodiment;

FIG. 3 is a schematic diagram of an information processing system according to a second embodiment;

FIG. 4 is a schematic diagram illustrating contents of an adjustment table used in the second embodiment;

FIG. 5 is a schematic diagram of a chiller according to a third embodiment;

FIG. 6 is a schematic diagram of an information processing system according to a fourth embodiment;

FIG. 7 is a schematic diagram of an information processing system according to a fifth embodiment;

FIG. 8 is a circuit diagram of a token control unit according to the fifth embodiment; and

FIG. 9 is a flowchart for explaining a method of controlling the information processing system according to the fifth embodiment.

### DESCRIPTION OF EMBODIMENTS

Embodiments will be described below with reference to the accompanying drawings.

### First Embodiment

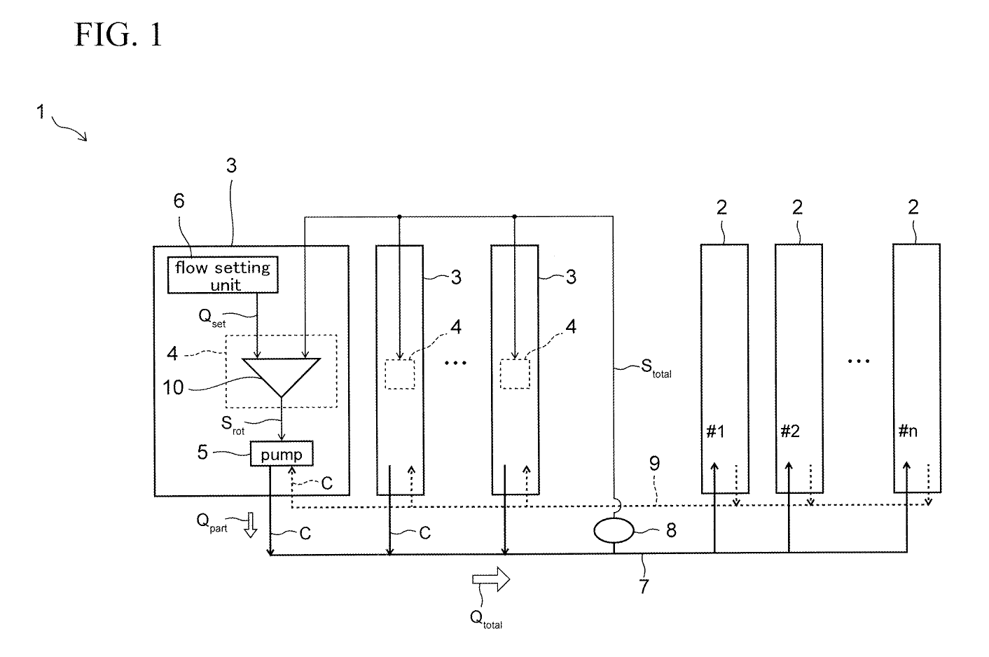

FIG. 1 is a schematic diagram of an information processing system according to a first embodiment.

This information processing system 1 includes a plurality of information processing devices 2 such as servers and computers, and a plurality of chillers 3 configured to circulate cooling water C to and from the information processing devices 2.

The information processing devices 2 are connected to the chillers 3 via a water supply line 7. The cooling water C outgoing from the chillers 3 are merged in the water supply line 7 and then distributed to the respective information processing devices 2.

Then, the cooling water C, which is a primary cooling water, is circulated between the chillers 3 and the information processing devices 2, and heat exchange is performed between the primary cooling water and secondary cooling water which circulates in each information processing device 2 by using a heat exchanger (not illustrated) provided in each of the information processing devices 2. Then, the cooling water C that cools each information processing device 2 passes through a water drain line 9 and returns to each chiller 3.

The water supply line 7 is provided with a flow monitor unit 8 configured to monitor a total flow volume Qₜₒₜₐₗ, which is a sum of the flow volume of the cooling water C in each chiller 3. The result of monitor by the flow monitor unit 8 is outputted to each chiller 3 as total flow volume information Sₜₒₜₐₗ, whose contents includes the total flow volume Qₜₒₜₐₗ.

Note that the flow monitor unit 8 may be provided to the water drain line 9.

Although codes #1 to #n for identifying the plurality of the information processing devices 2 are respectively annexed to the devices 2, the number of the information processing devices 2 is not particularly limited. For example, only one information processing device 2 may be provided.

Meanwhile, the chillers 3 are arranged in parallel with one another along a flow path of the cooling water C. Each chiller 3 includes an adjustment unit 4, a pump 5, and a flow setting unit 6. In addition, each chiller 3 is provided with an unillustrated heat exchanger.

Among them, the pump 5 cools the cooling water C returning from the water drain line 9 down to a predetermined temperature by using the unillustrated heat exchanger, and then delivers the cooling water C to the water supply line 7 again. In the following, a flow volume of the cooling water C per the chiller 3 delivered by the pump 5 is referred to as an individual flow volume Qₚₐᵣₜ. The individual flow volume Qₚₐᵣₜ can be adjusted per each chiller 3 by using the adjustment unit 4 to be described later.

Meanwhile, the flow setting unit 6 outputs a set value Qₛₑₜ of the total flow volume Qₜₒₜₐₗ of the cooling water C to the adjustment unit 4.

The set value Qₛₑₜ is a value of the total flow volume Qₜₒₜₐₗ suitable for cooling the information processing devices 2. For example, a value of the total flow volume Qₜₒₜₐₗ capable of preventing the information processing devices 2 from excessive cooling or insufficient cooling may be obtained in advance by an experiment or a simulation, and this value can be adopted as the set value Qₛₑₜ.

Meanwhile, the adjustment unit 4 includes a comparator circuit 10 configured to compare the set value Qₛₑₜ with the total flow volume Qₜₒₜₐₗ and to output a rotation speed setting signal Sᵣₒₜ. The rotation speed setting signal Sᵣₒₜ is a signal for setting the number of rotations of the pump 5, which is used for adjusting the individual flow volume Qₚₐᵣₜ of the cooling water C to be delivered by the pump 5.

In this example, based on a result of comparison between the total flow volume Qₜₒₜₐₗ and the set value Qₛₑₜ compared by the adjustment unit 4, the adjustment unit 4 adjusts the individual flow volume Qₚₐᵣₜ of the cooling water C such that the total flow volume Qₜₒₜₐₗ comes close to the set value Qₛₑₜ.

For instance, when the total flow volume Qₜₒₜₐₗ is greater than the set value Qₛₑₜ as a result of comparison between the total flow volume Qₜₒₜₐₗ and the set value Qₛₑₜ compared by the adjustment unit 4, the adjustment unit 4 reduces the individual flow volume Qₚₐᵣₜ of the cooling water C, since it is highly probable that the information processing devices 2 fall into excessive cooling. On the other hand, when the total flow volume Qₜₒₜₐₗ is equal to or below the set value Qₛₑₜ as a result of comparison between the total flow volume Qₜₒₜₐₗ and the set value Qₛₑₜ compared by the adjustment unit 4, the adjustment unit 4 increases the individual flow volume Qₚₐᵣₜ of the cooling water C, since it is highly probable that the information processing devices 2 fall into insufficient cooling.

Next, a method of controlling the information processing system 1 will be described.

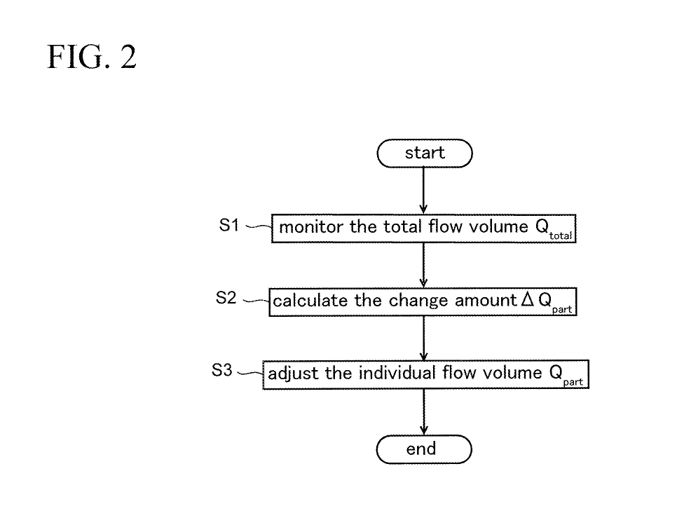

FIG. 2 is a flowchart for explaining a method of controlling the information processing system of the present embodiment.

First, in step S1, the flow monitor unit 8 monitors the total flow volume Qₜₒₜₐₗ of the cooling water

C flowing in the water supply line 7, and the adjustment unit 4 acquires the total flow volume Qₜₒₜₐₗ.

Next, in step S2, the adjustment unit 4 calculates a change amount ΔQₚₐᵣₜ of the individual flow volume Qₚₐᵣₜ. The change amount ΔQₚₐᵣₜ is increase or decrease amount required for the individual flow volume ΔQₚₐᵣₜ to bring the total flow volume Qₜₒₜₐₗ acquired in step S1 equal to the set value Qₛₑₜ.

The change amount ΔQₚₐᵣₜ is set in such a way as to reduce the individual flow volume Qₚₐᵣₜ when the total flow volume Qₜₒₜₐₗ is greater than the set value Qₛₑₜ.

Also, the change amount ΔQₚₐᵣₜ is set in such a way as to increase the individual flow volume Qₚₐᵣₜ when the total flow volume Qₜₒₜₐₗ is equal to or lower than the set value Qₛₑₜ.

Then, in step S3, the adjustment unit 4 adjusts the individual flow volume Qₚₐᵣₜ of the cooling water C by the above-described change amount ΔQₚₐᵣₜ.

By these steps, basic steps of the method of controlling the information processing system of the present embodiment are completed.

According to the above-described embodiment, the adjustment unit 4 adjusts the individual flow volume Qₚₐᵣₜ of the cooling water C per each chiller 3 on the basis of the result of comparison between the total flow volume Qₜₒₜₐₗ and the set value Qₛₑₜ compared by the adjustment unit 4, such that the total flow volume Qₜₒₜₐₗ of the cooling water C becomes equal to the set value Qₛₑₜ suitable for cooling the information processing devices 2. Therefore, when the total flow volume Qₜₒₜₐₗ temporarily drops due to a breakdown of any one of the chillers 3, it is possible to recover the total flow volume Qₜₒₜₐₗ by causing the remaining chillers 3 to increase their individual flow volume Qₚₐᵣₜ, thereby preventing the information processing devices 2 from falling into insufficient cooling.

Especially, in the case of providing the plurality of the information processing devices 2 as in this example, the above-described recovery of the total flow volume Qₜₒₜₐₗ can avoid the risk that the all of the information processing devices 2 simultaneously fall into insufficient cooling or breakdowns.

Moreover, since each chiller 3 cooperatively adjusts the total flow volume Qₜₒₜₐₗ as described above, the chillers 3 can compensate their differences in performance with each other, and hence the plurality of the chillers 3 need not have the same performance. Thus, it is possible to construct the information processing system 1 by using the chillers 3 of various performances which are already owned, and thus to eliminate waste of cost while effectively utilizing the own resources.

### Second Embodiment

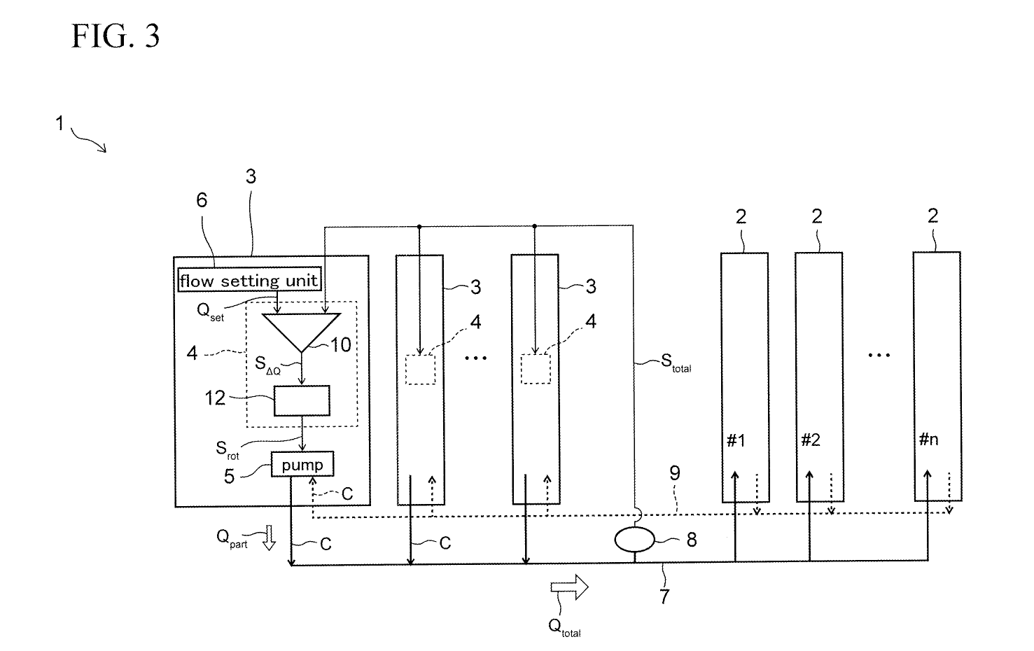

FIG. 3 is a schematic diagram of the information processing system 1 according to a second embodiment.

Note that constituents in FIG. 3 which are the same as those explained in the first embodiment will be denoted by the same reference numerals as those in the first embodiment, and descriptions thereof will be omitted in the following descriptions.

As illustrated in FIG. 3, in the present embodiment, the adjustment unit 4 of each chiller 3 includes an adjustment table 12 that is a storage device such as a RAM (random access memory).

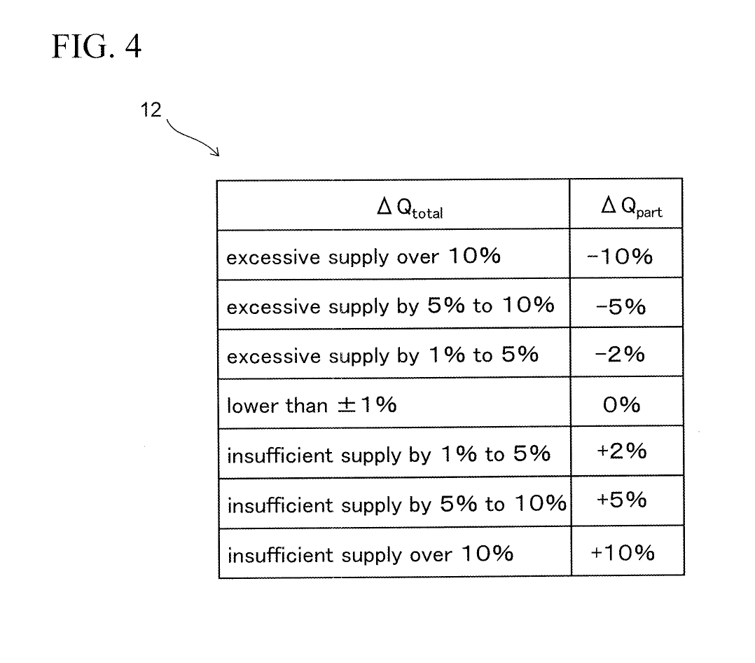

FIG. 4 is a schematic diagram illustrating contents stored in the adjustment table 12.

In the adjustment table 12, a total change rate ΔQₜₒₜₐₗ(=(Qₜₒₜₐₗ−Qₛₑₜ)/Qₜₒₜₐₗ) is associated with an individual change rate ΔQₚₐᵣₜ of the individual flow volume Qₚₐᵣₜ corresponding to the total change rate ΔQₜₒₜₐₗ. Here, the total change rate ΔQₜₒₜₐₗ is obtained by dividing the difference between the total flow volume Qₜₒₜₐₗ and the set value Qₛₑₜ, which represents the result of comparison between the total flow volume Qₜₒₜₐₗ and the set value Qₛₑₜ compared by the adjustment unit 4 as described above, by the total flow volume Qₜₒₜₐₗ.

The individual change rate ΔQₚₐᵣₜ is an adjustment parameter for the individual flow volume Qₚₐᵣₜ required for bringing the total change rate ΔQₜₒₜₐₗ equal to zero. The individual change rate A Qₚₐᵣₜ can be set per each chiller 3 in accordance with the performance of the chiller 3.

Note that the above-described adjustment table 12 is an example of change rate information.

As described above, the total change rate Qₜₒₜₐₗ is the value obtained by dividing a change amount (Qₜₒₜₐₗ−Qₛₑₜ) representing the result of comparison between the total flow volume Qₜₒₜₐₗ and the set value Qₛₑₜ compared in the adjustment unit 4 by the total flow volume Qₜₒₜₐₗ. However, the change amount (Qₜₒₜₐₗ−Qₛₑₜ) before being divided by the value Qₜₒₜₐₗ may be used instead of the total change rate Qₜₒₜₐₗ. This is also the case for the individual change rate ΔQₚₐᵣₜ.

Reference is made to FIG. 3 again.

In the present embodiment, the comparator circuit 10 provided in the adjustment unit 4 generates a difference signal S_{ΔQ} representing the difference ΔQ between the total flow volume Qₜₒₜₐₗ and the set value Qₛₑₜ on the basis of the result of comparison between the total flow volume Qₜₒₜₐₗ and the set value Qₛₑₜ. Then, the adjustment unit 4 refers to the adjustment table 12, thereby acquiring either the individual change rate ΔQₚₐᵣₜ or the above described change amount of the individual flow volume Qₚₐᵣₜ corresponding to the difference ΔQ. Thereafter, the adjustment unit 4 adjusts the individual flow volume Qₚₐᵣₜ by outputting to the pump 5 the rotation speed setting signal Sᵣₒₜ required for increasing or decreasing the individual flow volume Qₚₐᵣₜ by the change rate ΔQₚₐᵣₜ or above described change amount.

According to the present embodiment, it is possible to set the change rate ΔQₚₐᵣₜ or the change amount in the adjustment table 12 in accordance with the performance of each chiller 3, and thereby to obtain the optimum individual flow volume Qₚₐᵣₜ per each chiller 3.

### Third Embodiment

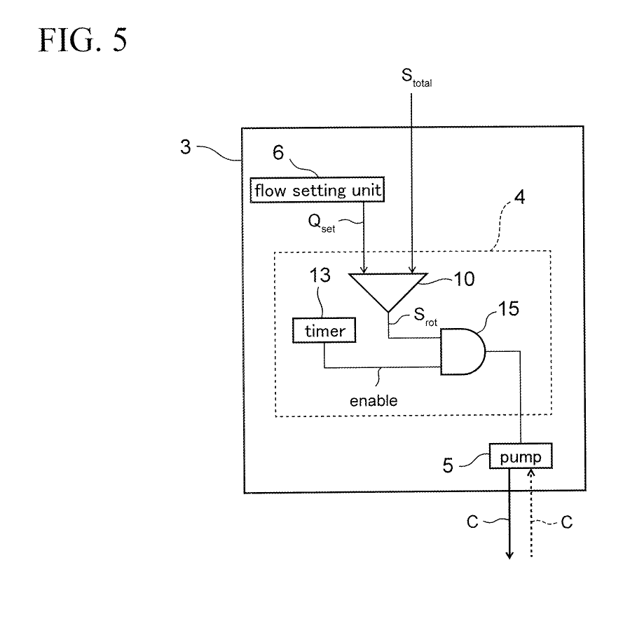

FIG. 5 is a schematic diagram of the chiller 3 according to a third embodiment.

Note that constituents in FIG. 5 which are the same as those explained in the first embodiment will be denoted by the same reference numerals as those in the first embodiment, and descriptions thereof will be omitted in the following descriptions.

As illustrated in FIG. 5, in the present embodiment, each adjustment unit 4 includes a timer 13, and an AND gate 15 configured to perform a logical multiplication.

The timer 13 periodically generates an enable signal “enable” and outputs the enable signal “enable” to the AND gate 15. The enable signal “enable” is a signal expressed by one bit for example, which is set to a high level in an enabled mode and is set to a low level in a mode other than the enabled mode.

Although a timing for generating the enable signal “enable” is not particularly limited, the enable signal “enable” can be generated with a period of 5 to 10 minutes, for example.

Meanwhile, the output signal from the comparator circuit 10 and the enable signal “enable” are inputted to the AND gate 15. As described in the first embodiment, the output signal of the comparator circuit 10 is the rotation speed setting signal Sᵣₒₜ.

Then, the AND gate 15 performs the logical multiplication operation using the output signal from the comparator circuit 10 and the enable signal “enable”, and thus outputs the rotation speed setting signal Sᵣₒₜ only when the enable signal “enable” is at the high level.

Accordingly, in the present embodiment, the rotation speed setting signal Sᵣₒₜ is outputted to the pump 5 with the same frequency as the frequency of generation of the enable signal “enable”. As a consequence, the individual flow volume Qₚₐᵣₜ is adjusted periodically.

Here, as for clock times to adjust the individual flow volumes Qₚₐᵣₜ, all the chillers 3 may be adjusted at the same clock time or the chillers 3 may be adjusted at different clock times from one another.

However, when all of the flow setting units 6 of the chillers 3 adjust the individual flow volumes Qₚₐᵣₜ at the same time, the total flow volume Qₜₒₜₐₗ may temporarily fluctuate by a large amount and it may take a long time for the value of the total flow volume Qₜₒₜₐₗ to converge. Therefore, it is preferable to change the timings of adjusting the individual flow volumes Qₚₐᵣₜ by the flow setting units 6 per chillers 3, and thus to suppress the fluctuation of the total flow volume Qₜₒₜₐₗ so as to promptly bring the value of the total flow volume Qₜₒₜₐₗ close to the set value Qₛₑₜ.

According to the present embodiment, each chiller 3 periodically adjusts the individual flow volume Qₚₐᵣₜ by using the flow setting unit 6. Thus, it is possible to periodically compensate the excess or deficiency of the total flow volume Qₜₒₜₐₗ.

### Fourth Embodiment

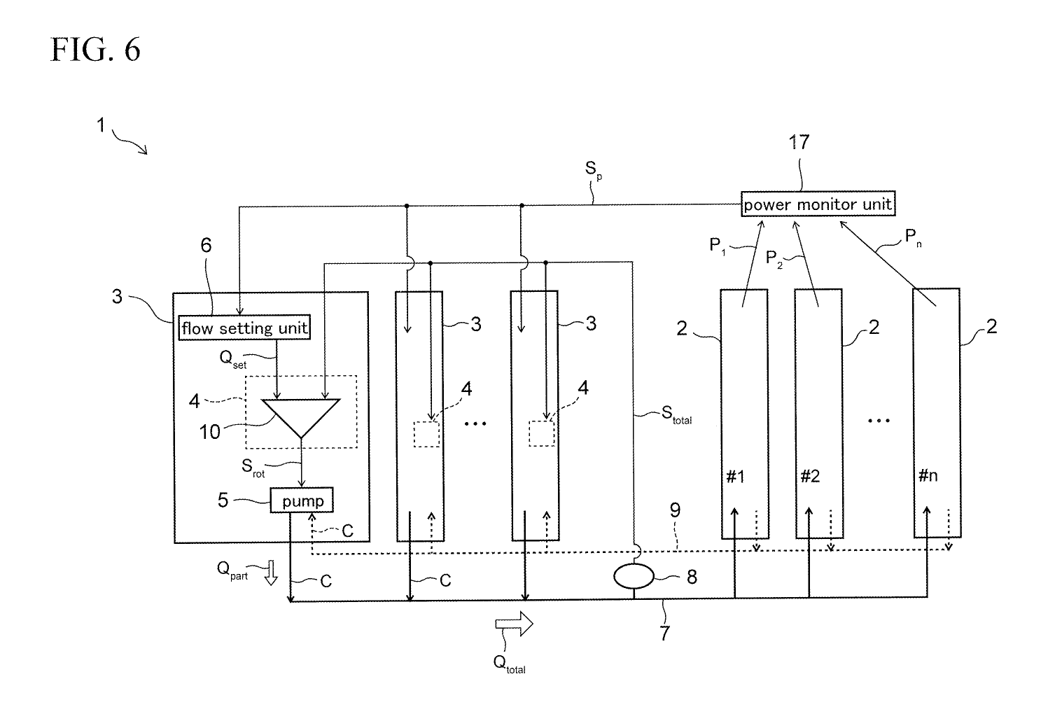

FIG. 6 is a schematic diagram of the information processing system according to a fourth embodiment.

Note that constituents in FIG. 6 which are the same as those explained in the first embodiment will be denoted by the same reference numerals as those in the first embodiment, and descriptions thereof will be omitted in the following descriptions.

As illustrated in FIG. 6, in the present embodiment, the information processing system 1 includes a power monitor unit 17 configured to monitor power consumption P₁ to Pₙ.

The power consumptions P₁ to Pₙ are respectively power consumption in the information processing devices 2 with the annexed codes #1 to # n. For example, when a plurality of servers are provided in the information processing device 2 with the annexed code # i, the total sum of the power consumption in all of these servers becomes the power consumption Pᵢ.

Meanwhile, the power monitor unit 17 is a server for example, which calculates the total sum P (=P₁+P₂+ . . . +Pₙ) of the above-mentioned power consumption P₁ to Pₙ and outputs the total sum P as a power signal Sₚ to each chiller 3.

Then, the flow setting unit 6 of each chiller 3 changes the set value Qₛₑₜ on the basis of the power signal Sₚ.

The way to change the set value Qₛₑₜ is not particularly limited. In this example, the set value Qₛₑₜ is increased when the total sum P of the power consumption P₁ to Pₙ is increased, while the set value Qₛₑₜ is decreased when the total sum P of the power consumption P₁ to Pₙ is decreased.

Accordingly, when the total sum P is increased and temperature of each information processing device 2 tends to rise, then it is possible to increase the total flow volume Qₜₒₜₐₗ so as to prevent each information processing device 2 from falling into insufficient cooling. On the other hand, when the total sum P is decreased and the temperature of each information processing device 2 tends to drop, then it is possible to decrease the total flow volume Qₜₒₜₐₗ so as to prevent each information processing device 2 from falling into excessive cooling.

According to the present embodiment, the set value Qₛₑₜ is changed in accordance with the total sum P of the power consumption P₁ to Pₙ. As a consequence, it is possible to obtain the total flow volume Qₜₒₜₐₗ suitable for operating conditions of the respective information processing devices 2.

Particularly, in the computer such as the server used as the information processing device 2, an amount of heat generation changes from moment to moment due to a load variation or maintenance work. In this respect, the method to adjust the total flow volume Qₜₒₜₐₗ based on the power consumption, as in the present embodiment, is highly advantageous for the computer such as the server.

### Fifth Embodiment

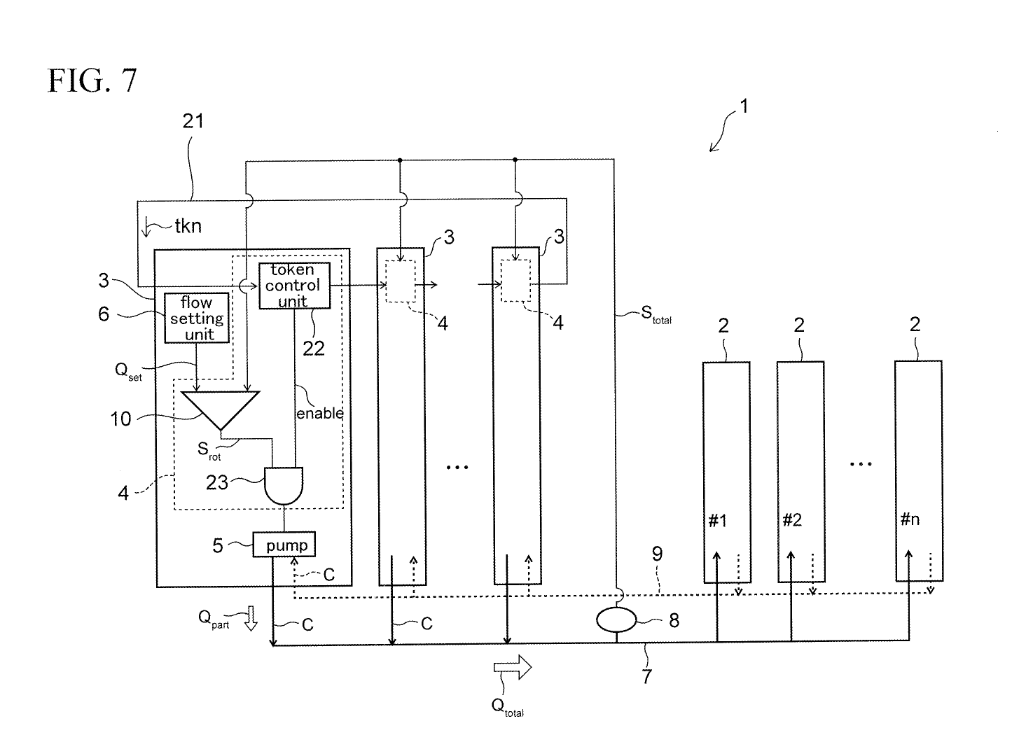

FIG. 7 is a schematic diagram of the information processing system according to a fifth embodiment.

Note that constituents in FIG. 7 which are the same as those explained in the first embodiment will be denoted by the same reference numerals as those in the first embodiment, and descriptions thereof will be omitted in the following descriptions.

As illustrated in FIG. 7, in the present embodiment, the adjustment units 4 of the chillers 3 are connected in the form of a ring by using a link 21.

Moreover, each adjustment unit 4 is provided with a token control unit 22 and an AND gate 23, and a token “tkn” generated by the token control unit 22 is caused to circulate the link 21.

The token control unit 22 outputs an enable signal “enable” to the AND gate 23 when the token control unit 22 receives the token “tkn” from the link 21. The enable signal “enable” is a one bit signal for example, which is set to a high level in an enabled mode and is set to a low level in a mode other than the enabled mode.

On the other hand, the enable signal “enable” and the rotation speed setting signal Sᵣₒₜ from the comparator circuit 10 are inputted to the AND gate 23.

Then, the AND gate 23 performs a logical multiplication operation using the enable signal “enable” and the rotation speed setting signal Sᵣₒₜ, and thus outputs the rotation speed setting signal Sᵣₒₜ to the pump 5 only when the enable signal “enable” is at the high level.

Accordingly, in the present embodiment, only the flow setting unit 6 of the chiller 3 which receives the token “tkn” from the link 21 adjusts the individual flow volume Q_{part,} while the individual flow volume Qₚₐᵣₜ of each of the remaining chillers 3 is maintained at the value at a point of time when they received the token “tkn” last time.

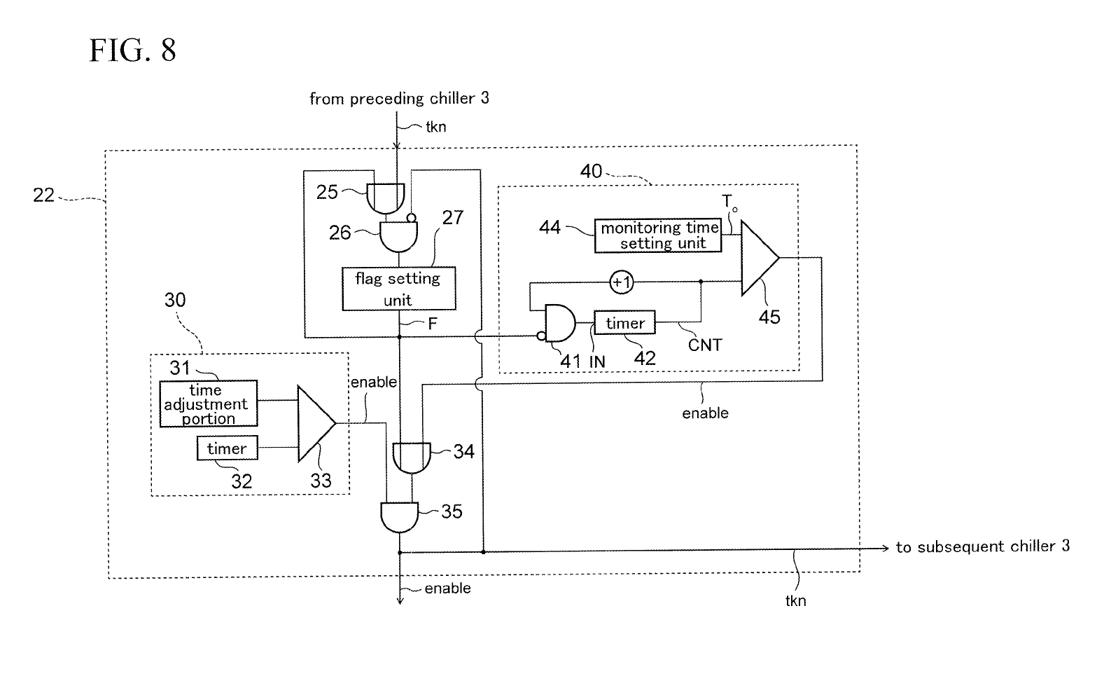

FIG. 8 is a circuit diagram of the token control unit 22.

As illustrated in FIG. 8, the token control unit 22 includes AND gates 26 and 35, a flag setting unit 27 for token effective flag, OR gates 25 and 34, a time adjustment unit 30, and an anomaly monitor unit 40 for a token anomaly.

The token “tkn” is inputted from the preceding chiller 3 to the AND gate 26 via the OR gate 25.

Here, the token “tkn” is a one bit signal having the same pulse width as that of an unillustrated clock signal, for example. The token “tkn” is deemed to be present when the clock signal is at a high level, and absent when the clock signal is at a low level.

At the lowering edge of the token “tkn” outputted form the AND gate 26, the flag setting unit 27 sets a one bit flag F to a high level.

The flag F is inputted to the AND gate 26 via the OR gate 25. Accordingly, even when the token “tkn” becomes the low level, one of the input terminals of the AND gate 26 is maintained at the high level. Hence, even when the token “tkn” is at the low level, the flag setting unit 27 keep the flag F at the high level as long as an inverted signal inputted to the other input terminal of the AND gate 26 is at the low level.

Then, the flag F is inputted to the AND gate 35 via the OR gate 34. At the same time, the enable signal “enable” of the time adjustment unit 30 is inputted to the AND gate 35.

The time adjustment unit 30 includes a time adjustment portion 31, a timer 32, and a comparator circuit 33.

The time adjustment portion 31 is configured to preset a clock time for performing the adjustment of the individual flow volume Qₚₐᵣₜ, and to output this clock time to the comparator circuit 33. This clock time is preferably made different between the two adjacent chillers 3 on the link 21 (see FIG. 7) by a time difference Δt. The time difference Δt is a period from a time point when one of the chillers 3 performs the adjustment of the individual flow volume Qₚₐᵣₜ to a time point when the total flow volume Qₜₒₜₐₗ is stabilized.

Then, the comparator circuit 33 compares the clock time outputted from the time adjustment portion 31 with a clock time outputted from the timer 32, and outputs the above-mentioned enable signal “enable” only when both of the clock times coincide with each other.

The enable signal “enable” is inputted to the AND gate 35. The AND gate 35 outputs the enable signal “enable” when the flag F is at the high level, which makes it possible to adjust the individual flow volume Qₚₐᵣₜ.

Here, the enable signal “enable” outputted form the AND gate 35 is outputted as the token “tkn” to the subsequent chiller 3. Moreover, the signal level of the enable signal “enable” is inverted, and then inputted to the aforementioned AND gate 26.

Thus, the output of the AND gate 26 becomes the low level at the time point when the token “tkn” is outputted form the AND gate 35. Accordingly, the flag setting unit 27 resets the flag F to the low level.

On the other hand, the anomaly monitor unit 40 is configured to monitor whether or not the token “tkn” is normally circulating around the link 21 (see FIG. 7). The anomaly monitor unit 40 includes an AND gate 41, a timer 42, a monitoring time setting unit 44, and a comparator circuit 45.

The flag F is inverted and then inputted to one of the input terminals of the AND gate 41.

The timer 42 is configured to output a count value “CNT” of the number of the pulse of the unillustrated clock signal. In synchronous with the clock signal, the timer 42 increments the count value “CNT” by one and returns the incremented count value “CNT” to an input end IN.

Here, the AND gate 41 outputs the count value “CNT” to the timer 42 only when the flag F is at the low level. On the other hand, when the flag F is at the high level, the input of the timer 42 becomes “0” and the count value “CNT” is reset accordingly.

In the meantime, the setting unit 44 outputs a preset default time T₀ to the comparator circuit 45. When the token “tkn” is not normally circulating, the flag F does not become at the high level even after the appreciably long time elapses. The aforementioned default time T₀ may be defined as a time period longer than a timeout period, by which one can determine that the token “tkn” is not normally circulating in this manner.

Then, the comparator circuit 45 compares the default time T₀ with the count value “CNT”, and outputs the enable signal “enable” to the OR gate 34 when the default time T₀ and the count value “CNT” coincide with each other.

In this way, even when the token “tkn” is not normally circulating, the enable signal “enable” is outputted from the AND gate 35 so as to enable the adjustment of the individual flow volume Qₚₐᵣₜ. Furthermore, since the token “tkn” is outputted form the token control unit 22 to the subsequent chiller 3, the token “tkn” circulates around the link 21 again.

Note that the anomaly monitor unit 40 may be omitted when the token “tkn” can reliably circulate around the link 21.

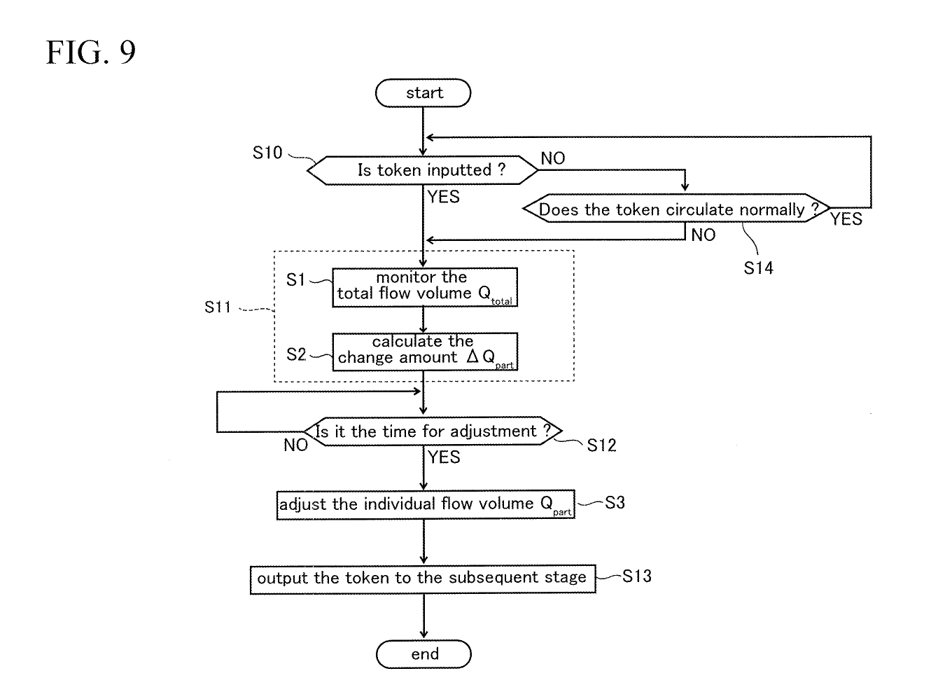

FIG. 9 is a flowchart for explaining a method of controlling the information processing system of the present embodiment.

First, in step S10, the flag setting unit 27 determines whether or not the token “tkn” is inputted from the preceding chiller 3.

Here, when the flag setting unit 27 determines that the token “tkn” is not inputted (NO), the flag setting unit 27 keeps the flag F at the low level, and the process proceeds to step S14.

In step S14, the anomaly monitor unit 40 determines whether or not the token “tkn” is normally circulating around the link 21. This determination is made by comparing the default time T₀ with the count value “CNT” as described previously. For example, the anomaly monitor unit 40 determines that the token “tkn” is not normally circulating around the link 21 (NO) when the count value “CNT” is equal to or above the default time T₀.

Then, when the anomaly monitor unit 40 determines that the token “tkn” is not normally circulating around the link 21 (NO), the comparator circuit 45 of the anomaly monitor unit 40 outputs the enable signal “enable” as described above, and then the process proceeds to step S11.

Note that when the anomaly monitor unit 40 determines that the token “tkn” is normally circulating around the link 21 in step S14 (YES), the process returns to step S10.

Here, step S14 may be omitted when the token “tkn” can reliably circulating around the link 21.

On the other hand, when it is determined in step S10 that the token “tkn” is inputted (YES), the flag setting unit 27 sets the flag F at the high level, and the process proceeds to step S11.

In step S11, the adjustment unit 4 performs step S1 and step S2 of the first embodiment in this order. Here, the adjustment unit 4 monitors the total flow volume Qₜₒₜₐₗ (step S1), and calculates the change rate ΔQₚₐᵣₜ or its change amount (step S2).

Next, the process proceeds to step S12, where the time adjustment unit 30 determines whether or not the time has come to perform the adjustment of the individual flow volume Qₚₐᵣₜ. Here, when the time has come to perform the adjustment (YES), the comparator circuit 33 of the time adjustment unit 30 outputs the above-mentioned enable signal “enable”.

On the other hand, when the time has not yet come to perform the adjustment (NO), step S12 is repeated until the comparator circuit 33 outputs the enable signal “enable”.

Then, after the comparator circuit 33 outputs the enable signal “enable”, the process returns to step S3 explained in the first embodiment.

As explained in the first embodiment, in step S3, the comparator circuit 10 of the adjustment unit 4 adjusts the individual flow volume Qₚₐᵣₜ of the cooling water C by the change amount ΔQₚₐᵣₜ, which is the result of comparison between the total flow volume Qₜₒₜₐₗ and the set value Qₛₑₜ compared in the adjustment unit 4.

Thereafter, the process proceeds to step S13, where the token control unit 22 outputs the token “tkn” to the subsequent chiller 3.

By these steps, basic steps of the method of controlling the information processing system of the present embodiment are completed.

According to the present embodiment, only one chiller 3 to which the token “tkn” is inputted adjusts the individual flow volume Qₚₐᵣₜ of the cooling water C, while the remaining chillers 3 do not adjust the individual flow volumes Qₚₐᵣₜ. Therefore, unlike the situation where the plurality of chillers 3 simultaneously adjust the individual flow volumes Qₚₐᵣₜ, the total flow volume Qₜₒₜₐₗ is prevented from significantly fluctuating, which in turn makes it possible to promptly bring the value of the total flow volume Qₜₒₜₐₗ close to the set value Qₛₑₜ.

Moreover, when the token “tkn” is not normally circulating around the link 21, the anomaly monitor unit outputs the enable signal “enable” and also outputs the token “tkn” to the subsequent stage. This enables the subsequent chiller 3 to adjust the individual flow volume Qₚₐᵣₜ and also allows the token “tkn” to circulate around the link 21 again. Accordingly, it is possible to avoid the situation where the adjustment of the individual flow volumes Qₚₐᵣₜ is stopped in all of the chillers 3.

In addition, by providing the time adjustment unit 30, it is possible to provide the time difference Δt between the clock times when the adjacent chillers 3 adjust the individual flow volumes Qₚₐᵣₜ. As a consequence, the one chiller 3 does not perform the adjustment of its individual flow volume Qₚₐᵣₜ until the total flow volume Qₜₒₜₐₗ is stabilized after the adjustment of the individual flow volume Qₚₐᵣₜ performed by the adjacent chiller 3. Thus, it is possible to stabilize the total flow volume Qₜₒₜₐₗ.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing system comprising:
a plurality of information processing devices cooled by cooling water;
a plurality of chillers each configured to circulate the cooling water to and from the plurality of the information processing devices;
a flow monitor unit configured to monitor a total flow volume, where the total flow volume being a sum of a flow volume of each cooling water of the plurality of the chillers; and
adjustment units each provided to each of the chiller, where the adjustment unit being configured to adjust an individual flow volume of the cooling water in the corresponding chiller, such that the total flow volume monitored by the flow monitor unit becomes equal to a set value suitable for cooling the plurality of the information processing devices.

2. The information processing system according to claim 1, wherein
each of the plurality of the chillers further comprises:
a storage device configured to store an information formed by associating a total change rate, being obtained by dividing a difference between the total flow volume and the set value by the total flow volume, with a change rate of the individual flow volume that corresponds to the total change rate,
wherein the adjustment unit adjusts the flow volume by the change rate of the individual flow volume on the basis of the information.

3. The information processing system according to claim 1, wherein
each of the information processing device further comprises:
a power monitor unit configured to monitor power consumption in each of the information processing device, and
a setting unit configured to set the set value,
wherein the setting unit changes the set value in accordance with an increase and decrease in the power consumption monitored by the power monitor unit.

4. The information processing system according to claim 1, wherein
the adjustment unit periodically performs the adjustment of the individual flow volume.

5. The information processing system according to claim 4, wherein clock times to perform the adjustment of the individual flow volume are different among the plurality of the chillers.

6. The information processing system according to claim 1, the system further comprising:
a link connecting the adjustment units included in the plurality of the chillers to one another in the form of a ring, and allowing a token to circulate around the link, wherein
the adjustment unit performs the adjustment of the individual flow volume in the corresponding information processing device on the basis of an input of the token.

7. The information processing system according to claim 6, wherein the adjustment unit comprises:
an anomaly monitor unit configured to enable the adjustment of the individual flow volume when the input of the token is absent at a predetermined clock time.

8. The information processing system according to claim 7, wherein the adjustment unit comprises:
a time adjustment unit configured to set a clock time to perform the adjustment of the individual flow volume,
wherein the clock times are different between two of the chillers adjacent to each other in the link.

9. A method of controlling an information processing system, the method comprising:
monitoring, by a flow monitor unit, a total flow volume of a cooling water of a plurality of chillers each configured to circulate the cooling water to and from a plurality of information processing devices that are cooled by the cooling water, where the total flow volume being a sum of a flow volume of each cooling water of the plurality of the chillers; and
adjusting, by each of an adjustment unit provided to each of the plurality of the chillers, an individual flow volume of the chiller such that the total flow volume monitored by the flow monitor unit becomes equal to a set value suitable for cooling the plurality of the information processing devices.
